(19) United States
(12) Patent Application Publication
(10) Pub. No.: US 2011/0248755 A1
(43) Pub. Date: Oct. 13, 2011

(54) CROSS-FEEDBACK PHASE-LOCKED LOOP FOR DISTRIBUTED CLOCKING SYSTEMS

(76) Inventors: William C. Hasenplaugh, Boston, MA (US); Olivier Franza, Boston, MA (US); Kambiz R. Munshi, Shrewsbury, MA (US)

(21) Appl. No.: 12/756,979

(22) Filed: Apr. 8, 2010

(51) Int. Cl. H03L 7/08

(52) U.S. Cl. 327/157; 327/156

(57) ABSTRACT

According to various embodiments, a cross-feedback phase-locked loop (XF-PLL) may include a secondary phase/frequency detector to detect the phase/frequency differences between two adjacent domains and feed the phase/frequency differences back into the main feedback loop of the XF-PLL, thereby reducing accumulated jitter and inter-domain clock skew in a distributed clocking system. Other embodiments may be described and claimed.

### TECHNICAL FIELD

Embodiments of the present disclosure relate to the field of integrated circuits, in particular, phase-locked loop for distributed clocking systems.

### BACKGROUND

Modularity requirements in distributed clocking systems for integrated circuits, e.g., multi-core microprocessors, may create new technical challenges for infrastructure design. In a distributed clocking system, each self-contained block of logic circuitry, also referred to as a domain or a slice, may contain its own phase-locked loop (PLL) for generating the clock information for that domain. The clock information generated by the PLL may be an approximate square wave clock signal that can vary with time in instantaneous frequency and phase. In a distributed clocking system, all the PLL's may be driven by the same reference clock. However, each PLL may generate clock information that has a slight shift in its phase and/or frequency compared to the other PLL's, which may be represented by jitter and inter-domain clock skew.

Integrated circuits, in particular, analog circuits, may accumulate jitter as they drift in time. Jitter may represent the temporal inaccuracy of successive clock signal edges at the same location. Jitter may be of many different kinds Period jitter may refer to the difference between the actual clock period and an ideal perfectly matched clock period. Cycle-to-cycle jitter (or short-term jitter) may refer to the worst-case difference between any two successive edges of the clock signal. Accumulated jitter may refer to the difference between two edges of the clock signal situated a given number of clock periods apart. Accumulated jitter may be defined as the standard deviation of the phase of a PLL output, relative to an ideal perfectly matched clock.

Skew may represent the spatial inaccuracy of the same clock signal edge at different locations. An ideal perfectly matched clock may have a zero skew under no process/voltage/temperature variations. Skew may be defined as the standard deviation of the phase difference between two PLL outputs.

Inter-domain clock skew and accumulated jitter within a domain may reduce data communication performance.

### BRIEF DESCRIPTION OF THE DRAWINGS

Embodiments of the present disclosure will be described by way of exemplary illustrations, but not limitations, shown in the accompanying drawings in which like references denote similar elements, and in which:

FIG. 1 illustrates a block diagram of an example distributed clocking system including multiple domains, in accordance with various embodiments;

FIG. 2 illustrates a cross-feedback phase-locked loop in accordance with various embodiments;

FIG. 3 illustrates in more detailed fashion various components of a cross-feedback phase-locked loop, in accordance with various embodiments;

FIG. 4 illustrates another example cross-feedback phase-locked loop, in accordance with various embodiments;

FIG. 5 illustrates simulation results of the cross-feedback phase-locked loop on a) jitter reduction, and b) inter-domain clock skew reduction in accordance with various embodiments; and

FIG. 6 illustrates a flow diagram of a portion of example operation of a cross-feedback phase-locked loop.

FIG. 7 illustrates a block diagram of an apparatus configured to practice the circuits and methods disclosed herein in accordance with various embodiments.

### DETAILED DESCRIPTION OF ILLUSTRATIVE EMBODIMENTS

In the following detailed description, reference is made to the accompanying drawings which form a part hereof, and in which are shown by way of illustration embodiments in which the invention may be practiced. It is to be understood that other embodiments may be utilized and structural or logical changes may be made without departing from the scope of the present invention. Therefore, the following detailed description is not to be taken in a limiting sense, and the scope of embodiments in accordance with the present invention is defined by the appended claims and their equivalents.

Various operations may be described as multiple discrete operations in turn, in a manner that may be helpful in understanding embodiments of the present invention; however, the order of description should not be construed to imply that these operations are order dependent.

The terms “coupled” and “connected,” along with their derivatives, may be used. It should be understood that these terms are not intended as synonyms for each other. Rather, in particular embodiments, “connected” may be used to indicate that two or more elements are in direct physical or electrical contact with each other. “Coupled” may mean that two or more elements are in direct physical or electrical contact. However, “coupled” may also mean that two or more elements are not in direct contact with each other, but yet still cooperate or interact with each other.

For the purposes of the description, a phrase in the form “A/B” or in the form “A and/or B” means (A), (B), or (A and B). For the purposes of the description, a phrase in the form “at least one of A, B, and C” means (A), (B), (C), (A and B), (A and C), (B and C), or (A, B and C). For the purposes of the description, a phrase in the form “(A)B” means (B) or (AB) that is, A is an optional element.

The description may use the phrases “in an embodiment,” or “in embodiments,” which may each refer to one or more of the same or different embodiments. Furthermore, the terms “comprising,” “including,” “having,” and the like, as used with respect to embodiments of the present invention, are synonymous.

Throughout this disclosure, the term “circuit” may refer to a complete integrated circuit, or a part thereof

In various embodiments, an apparatus may include a first domain having a first phase-locked loop (PLL); a second domain having a second PLL, the second domain being adjacent to the first domain, in which the first PLL may be configured to receive a first input from an output of the first PLL and a second input from an output of the second PLL, and the second PLL may be configured to receive a third input from the output of the first PLL and a fourth input from the output of the second PLL to form a cross feedback relationship between the first PLL and the second PLL.

In various embodiments, the first PLL may further include a main phase or frequency detector configured to receive the first input; a main charge pump and a voltage controlled oscillator (VCO) coupled to the main phase or frequency detector to form a main feedback loop; and a first secondary phase or frequency detection unit coupled to the main feedback loop, the first secondary phase or frequency detection unit configured to receive the second input and the output of the first PLL.

In various embodiments, the output of the first PLL may be coupled to the second PLL of the second domain via another secondary phase or frequency detector unit coupled to the second PLL.

In various embodiments, the first secondary phase or frequency detector unit may comprise a secondary phase/frequency detector and a secondary charge pump.

In various embodiments, the first secondary phase or frequency detector unit comprises a lead/lag detector configured to cause the main charge pump to increase or decrease a current by a predefined amount.

In various embodiments, the first secondary phase or frequency detector unit may be configured to be disabled during initial locking period of the first PLL.

In various embodiments, the first secondary phase or frequency detector unit may comprise a phase detector.

In various embodiments, the secondary charge pump may be structurally similar to the main charge pump and configured to produce a fraction of current compared to the main charge pump.

In various embodiments, the first PLL may further comprise a second secondary phase or frequency detection unit coupled to the main feedback loop, the second secondary phase or frequency detection unit configured to receive the output of the first PLL and an output from a third PLL of a third domain to form a cross feedback relationship with the third domain, the third domain being adjacent to the first domain.

In various embodiments, the apparatus may be a multi-core microprocessor comprising a plurality of domains with a one-dimensional or two-dimensional layout.

In various embodiments, a method may include receiving, by a secondary phase frequency detector unit disposed on an integrated circuit comprising multiple domains, a first input signal based on an output of a main phase-locked loop (PLL) of a first domain and a second input signal based on an output of a second PLL of a second domain, the second domain being adjacent to the first domain; detecting, by the secondary phase or frequency detection unit, a phase or frequency difference between the first and the second input signal; and adjusting the output of the main PLL at least partially based on detected phase or frequency difference.

In various embodiments, the adjusting the output of the main PLL may further include adjusting an output of a main charge pump of the main PLL at least partially based on the detected phase or frequency difference.

In various embodiments, the secondary phase or frequency detector unit may comprise a lead/lag detector, and the main PLL comprises a charge pump, and the method may further include increasing or decreasing an output of the charge pump by a predefined amount at least partially based on whether a phase/frequency of the first input signal is leading or lagging with respect to the second input signal.

In various embodiments, the method may further include disabling the secondary phase/frequency detector unit during initial locking period of the main PLL.

In various embodiments, the secondary phase or frequency detector unit may comprise a secondary charge pump, and the method may further include adjusting an output of the secondary charge pump based on a secondary charge pump v. main charge pump current ratio.

In various embodiments, a system may include a memory controller disposed on a die; a plurality of execution units disposed on a die coupled to the memory controller, wherein respective ones of the plurality of execution units adjacent to one or more neighboring executing units and the respective ones of the plurality of execution units may further include a cross-feedback phase-locked loop (XF-PLL) configured to receive a main input from an output of the XF-PLL and one or more secondary inputs respectively from one or more outputs of one or more XF-PLL's of the one or more neighboring execution units.

In various embodiments, the XF-PLL may further include a main phase or frequency detector configured to receive the main input; a main charge pump and a voltage controlled oscillator (VCO) coupled to the main phase or frequency detector to form a main feedback loop; one or more secondary phase or frequency detector units coupled to the main feedback loop, the one or more secondary phase or frequency detector configured to respectively receive the one or more secondary inputs.

In various embodiments, the one or more secondary phase or frequency detector may be configured to receive an output of the VCO.

In various embodiments, respective ones of the one or more secondary phase or frequency detector units may comprise a secondary phase/frequency detector and a secondary charge pump.

In various embodiments, the one or more secondary phase or frequency detector units may comprise a lead/lag detector configured to cause the main charge pump to increase or decrease a current by a predefined amount.

In various embodiments, respective ones of the one or more secondary phase or frequency detector units may comprise a phase detector.

In various embodiments, the secondary charge pump may be structurally similar to the main charge pump and configured to produce a fraction of current compared to the main charge pump.

Modularity requirements in distributed clocking systems, e.g., multi-core microprocessors, may create new technical challenges for infrastructure design. In a distributed clocking system, each domain may contain various components, such as a processor core, a memory controller, a cache, or a domain interconnect, etc. Domains may be coupled via abutment. Each domain may have its own PLL for generating its own clock information. All PLL's may be driven by the same low frequency (e.g., 100/133 MHz) reference clock. All the domains may run at the same (but variable) frequency generated by its PLL. Clock information generated by the PLL may cross domains through an interconnect interface. For adequate data transfer performance, the clock information generated by the PLL may need to be matched in phase, frequency or both (phase/frequency) quite accurately across all the domains. Additionally, the PLL may be subject to tighter specifications in terms of jitter, and in particular, accumulated jitter, to ensure that clock drift between adjacent domains may be kept within a tolerance range for single cycle data transfers through the interconnect.

According to various embodiments, a cross-feedback phase-locked loop (XF-PLL) may include a secondary phase/frequency detector to detect the phase/frequency differences between two adjacent domains and feed the phase/frequency differences back into the main feedback loop of the XF-PLL, thereby reducing accumulated jitter and inter-domain clock skew in a distributed clocking system.

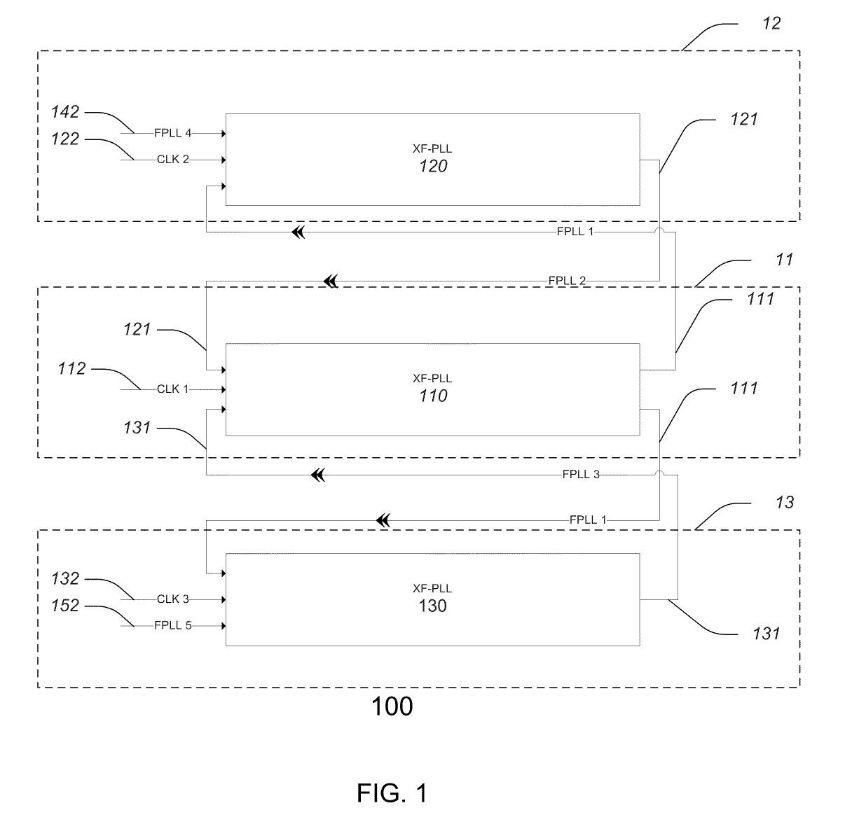

FIG. 1 illustrates a block diagram of an example distributed clocking system 100 including multiple domains, in accordance with various embodiments. In embodiments, as illustrated, a distributed clocking system 100 may include three domains, 11, 12, and 13, respectively, illustrated by areas surrounded by the dashed lines, coupled to each other as shown. Domain 11 may be adjacent to two domains 12 and 13. Domains 12 and 13 may each be adjacent to only one domain, domain 11. For ease of understanding, only three domains configured in one-dimensional (linear) fashion are shown in FIG. 1, however the present disclosure is not so limited, and may be practiced with any number of domains. In various embodiments, the distributed clocking system 100 may comprise more or less number of domains, and the domains may be configured in two-dimensional or three-dimensional fashion through die-stacking Accordingly, the number of adjacent domains may vary depending on the topology of the distributed clocking system and the location of a particular domain. For example, in a multiple domain system configured in two-dimensional fashion, a domain located in a corner may have three adjacent domains, whereas a domain located in the center may have eight adjacent domains, including the adjacent domains that are located diagonally.

In embodiments, domains 11-13 may each include a XF-PLL 110, 120 and 130, respectively. Each domain may also include additional components, such as a processor core, a cache, a memory controller, or a domain interconnect, etc. For ease of understanding, these additional components are not shown in FIG. 1.

In embodiments, as illustrated, each XF-PLL 110, 120 and 130 may be coupled with a reference clock, 112, 122 and 132 respectively. Each XF-PLL 110, 120 and 130 may also comprise a feedback loop between the reference clock and its own output clock information. Further details of this feedback loop will be provided in later parts of this disclosure. The reference clock 112, 122 and 132 may or may not be derived from the same reference clock.

The output 121 of the XF-PLL 120, and the output 131 of the XF-PLL 130 may be coupled to the input terminals of XF-PLL 110, and the output 111 of the XF-PLL 110 may be coupled to the input terminals of the XF-PLL 120 and XF-PLL 130, respectively. Accordingly, in addition to the reference clock, each XF-PLL may also receive/provide output from/to the XF-PLL's of the adjacent domains, thereby creating a cross-feedback relationship with the adjacent domains.

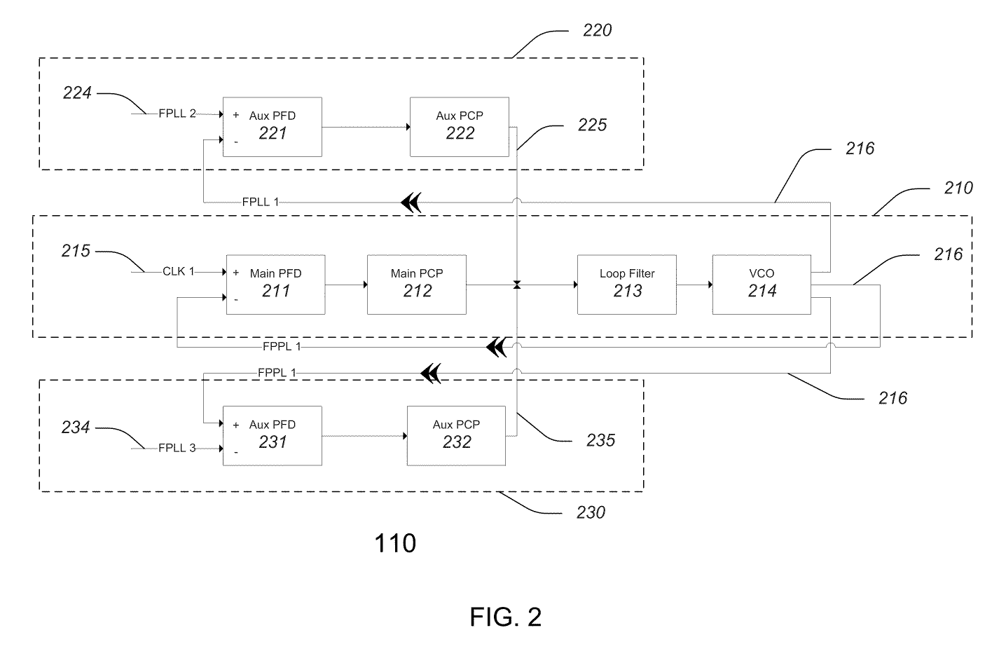

FIG. 2 illustrates in more detailed fashion the XF-PLL 110 for domain 11, in accordance with various embodiments. In various embodiments, XF-PLL's 120 and 130 may likewise be similarly configured.

In embodiments, the XF-PLL 110 may comprise a main PLL 210, which may include a main phase/frequency detector (PFD) 211, a main proportional charge pump (PCP) 212, a loop filter 213, and a voltage controlled oscillator (VCO) 214, coupled to each other as shown. In various embodiments, the main PLL 210 may also include other components, such as counters, multipliers, dividers, or low pass filters, etc., which are not shown for purpose of simplicity and clarity of illustration.

As illustrated, the reference clock 215 may be coupled to a first input terminal of the main PFD 211. A second input terminal of the main PFD 211 may be coupled to the output of the VCO 216 to form a main feedback loop. In embodiments, the frequency of the VCO output 216 may be higher than the frequency of the reference clock 215. Accordingly, in various embodiments, the main PFD 211 may be coupled to the VCO output 216 via one or more counters or dividers (not shown). The output of the main PFD 211 may be a voltage signal that is proportional to the phase/frequency difference between the reference clock 215 and the divided VCO output 216. The main PCP 212 may either sink (decrease) current or source (increase) current according to the output of the main PFD 211. The main PCP 212 and the loop filter 213 may control the bandwidth of the XF-PLL 110.

In embodiments, as illustrated, the XF-PLL 110 may comprise secondary phase/frequency detector units 220 and 230. In embodiments, the inter-domain phase/frequency detector unit 220 may be located at the boundaries between domains 11 and 12. The secondary phase/frequency detector unit 220 may comprise a secondary PFD 221 and a secondary PCP 222, which may have similar functionalities to the main PFD 211 and the main PCP 212. The first input terminal of the secondary PFD 221 may be coupled to the VCO output 216. The second input terminal of the secondary PFD 221 may be coupled to the VCO output 224 from domain 12 located adjacent to domain 11. In various embodiments, the output of the VCO 216 and 224 of respective domains 11 and 12 may be coupled to the input terminals of the secondary PFD 221 without passing through frequency dividers.

In various embodiments, the secondary PFD 221 may detect the inter-domain phase/frequency skew between domains 11 and 12 and may produce an output 225 proportional to the inter-domain phase/frequency skew. And the output 225 may be coupled to the loop filter 213 and VCO 214, thereby forming a secondary feedback loop. The secondary feedback loop may help track any phase/frequency drift between domains 11 and 12.

In embodiments, the secondary phase/frequency detector unit 230, including the secondary PFD 231 and the secondary PCP 232 may be likewise similarly configured to form another secondary feedback loop between domains 11 and 13. Accordingly, the phase/frequency difference between adjacent domains, as well as phase/frequency difference between each domain and the reference clock 215, may be fed back and accumulated in the VCO 214 in every clock cycle.

The additional feedback based on the illustrated secondary feedback loops between adjacent domains may reduce the inter-domain clock skew and the accumulated jitter and may optimize intra-domain communication latency, improve noise tolerance and improve stability through the use of robust feedback mechanism.

Even though FIG. 2 shows several individual components, in alternate embodiments, any one of these components may be combined with the one or more other components and/or be integrated into a single unit, or in other embodiments, further subdivided. For example, the main PFD 211 and the main PCP 212 may be integrated as a single component, or respectively further subdivided.

In various embodiments, the XF-PLL 200 may include additional components, e.g., switches (not shown), to disable the secondary feedback loops, including the secondary phase/frequency detector units 220 and 230, during the initial locking period of the main PLL 210. The secondary phase/frequency detector units 220, 230 may be enabled after the main PLL 210 has acquired the lock with respect to the reference clock 215. In various embodiments, when deemed necessary, the secondary phase/frequency detector units 220, 230 may also be disabled, and the cross-feedback effect may be eliminated, after a lock has been acquired by the main PLL 210. In various embodiments, the secondary feedback loop may be disabled without impacting the functionality or stability of the main PLL 210.

In various embodiments, the secondary PFD 221 may be similarly configured as to the main PFD 211. In various embodiments, the secondary PFD 221 may comprise simple phase detectors. In various embodiments, secondary PFD 231 may be likewise similarly configured as the secondary PFD 221.

In various embodiments, the secondary PCP 222 may be similarly configured as to the main PCP 312. In various embodiments, the secondary PCP 222 may comprise a scaled down version of the main PCP 212. The secondary PCP 222 may be scaled down by using circuits substantially identical or similar to the main PCP 212, but with some of the transistors in the current mirror portion of the PCP 222 disabled, so as to produce only a known fraction of the current in the secondary PCP 222. Using a scaled down version in the secondary PCP 222 may help ensure that the amount of correction generated by the secondary PCP 222 may be proportional to the phase/frequency differences between adjacent domains detected by the secondary PFD 221. It may also help ensure that the poles introduced by these secondary feedback loops are of high enough frequency as not to affect the stability of the main feedback loop. In various embodiments, secondary PCP 232 may be likewise similarly configured.

In various embodiments, secondary phase/frequency detector units 220, 230 may include controls (not shown) to turn on/off certain transistors in the secondary PCP 222 and 232 so that the secondary PCP v. main PCP current ratio may be tuned and controlled. The secondary PCP v. main PCP current ratio may determine the impact of the secondary feedback loop, as compared to the main feedback loop. A small secondary PCP v. main PCP current ratio may produce a small amount of cross-feedback correction and may have negligible effect in reducing skew and/or jitter. A big secondary PCP v. main PCP current ratio may lead to over-correction and negatively impact the stability of the XF-PLL. The optimum secondary PCP v. main PCP current ratio may be obtained by detailed stability analysis of a particular distributed clocking system. Simulation results may indicate a secondary PCP v. main PCP current ratio around 0.5 be optimum for some distributed clocking systems.

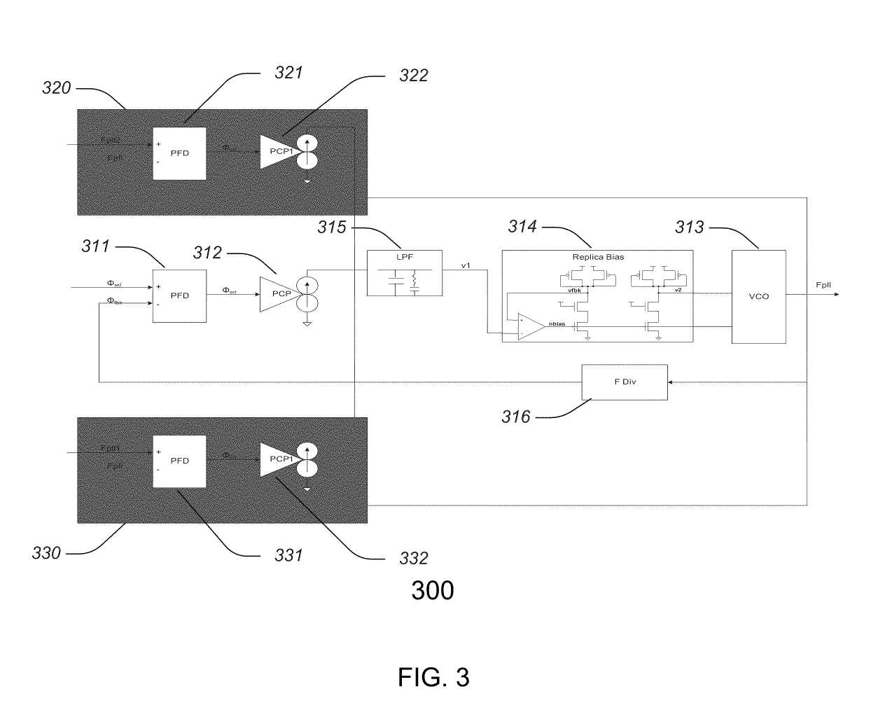

FIG. 3 illustrates in more detailed fashion a XF-PLL 300 in accordance with various embodiments. In embodiments, the XF-PLL 300 may include a main PFD 311, a main PCP 312, a low pass filter (LPF) 315, a replica bias 314, and a VCO 313. The output of the VCO 313 may be feedback and coupled to the main PFD 311 via frequency divider 316 to form the main feedback loop.

In embodiments, the XF-PLL 300 may comprise secondary phase/frequency detector units 320 and 330, shown in shaded area of FIG. 3, which may be configured to create the secondary feedback loops with the main PLL. The secondary phase/frequency detector units 320 and 330 may further comprise secondary PFDS 321, 331, and secondary PCPS 322, 332, respectively.

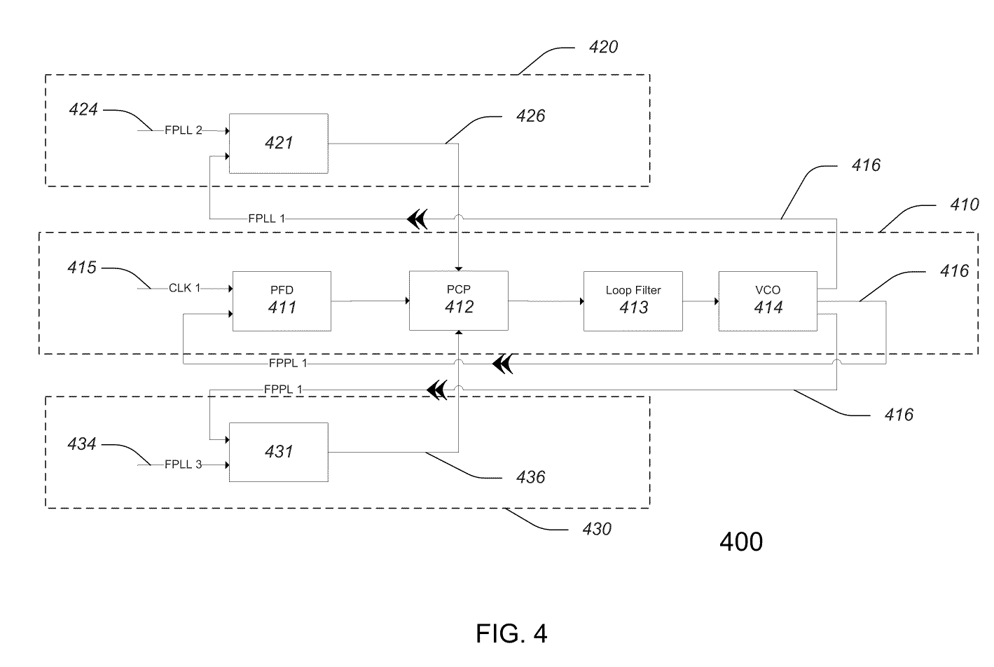

FIG. 4 illustrates another example XF-PLL in accordance with various embodiments. As illustrated, in embodiments, the XF-PLL 400 may include a main PLL 410 and secondary phase/frequency detector units 420, 430. The main PLL 410 may comprise similar components as to the XF-PLL 200 illustrated in FIG. 2, including a main PFD 411, a main PCP 412, a loop filter 413 and a VCO 414.

In embodiments, the secondary phase/frequency detector unit 420 may comprise a lead/lag detector 421. The lead/lag detector 421 may detect and generate a lead/lag output 426 indicating whether the phase/frequency of the VCO output 416 is leading or lagging with respect to the VCO output 424 of the adjacent domains. In various embodiments, this lead/lag output 426 may or may not be proportional to the inter-domain phase/frequency differences.

In various embodiments, lead/lag output 426 may be coupled to the main PCP 412. The main PCP 412 may either source or sink current by a pre-defined increment based on the lead/lag output 426. Using a lead/lag detector 421 may simplify the implementation and reduce the cost of the XF-PLL 400 as only a single PCP, i.e., the main PCP 412, may be used. In addition, it may also help ensure each domain to receive substantially the same amount of feedback, even though the amount of feedback may not be proportional to the phase/frequency difference between two adjacent domains. The effect of non-proportional correction applied by the main PCP 412 may be negligible when the amount of correction is small. In various embodiments, the secondary phase/frequency detector unit 430 may be likewise similarly configured.

In embodiments, test results may indicate that the reduction of inter-domain clock skew and accumulated jitter is more significant when multiple domains cross-feedback phase/frequency differences in a fully interconnected manner.

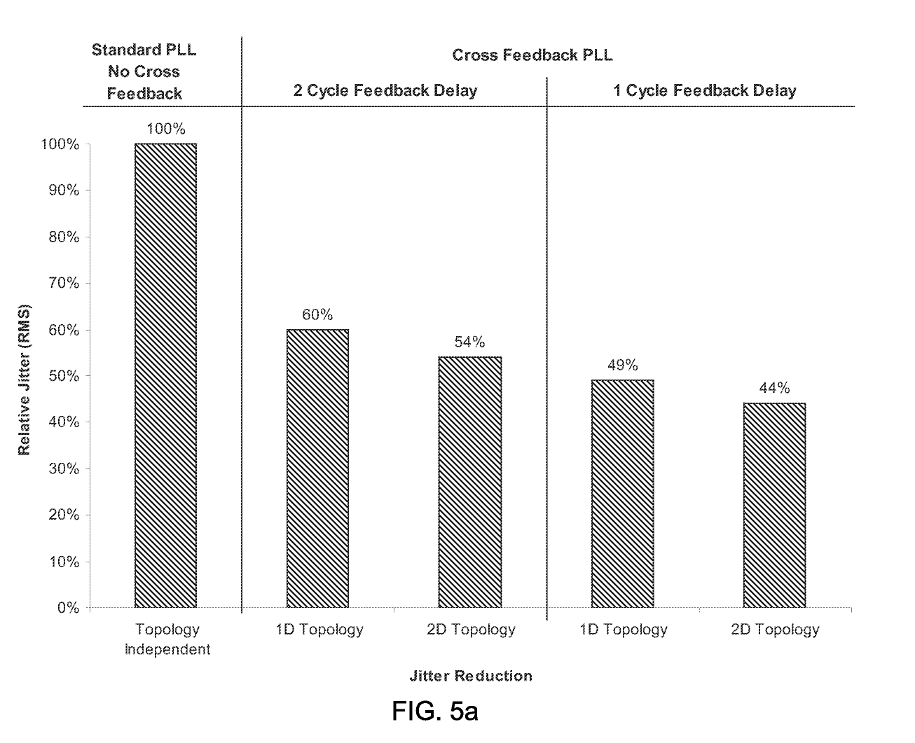

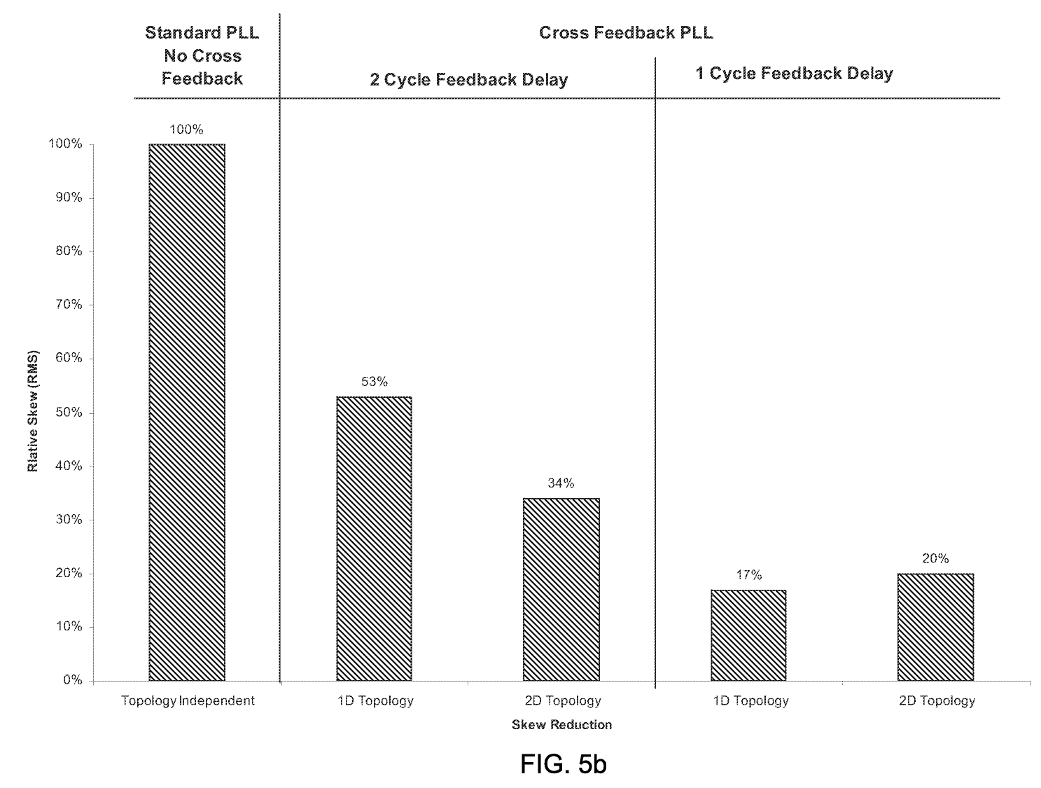

FIG. 5 illustrates simulation results showing the a) jitter reduction, and b) skew reduction by using the XF-PLL in accordance with various embodiments. Simulations may be performed on distributed clocking systems having eight domains configured in one-dimensional fashion (1×8) and two-dimensional fashion (2×4), based on feedback coefficient (the fraction of the phase/frequency difference that may be reflected in the VCO output) of 0.9 for 1 clock cycle feedback delay and 0.5 for 2 clock cycle feedback delay. As shown by simulation results, the XF-PLL may reduce accumulated jitter by about 40%-56% and inter-domain skew by 47%-83%, depending on the topology and feedback delays. In various embodiments, the feedback coefficient may be further controlled and optimized during laboratory tests by using actual devices, commercially available system boards, logic analyzers and assertion-based tools, etc.

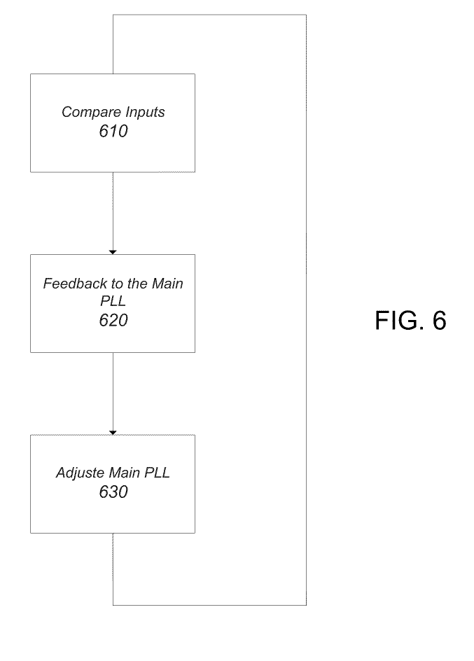

FIG. 6 illustrates a flow diagram of a portion of example operation of an XF-PLL as previously described. In block 610, the secondary PFD 221 may compare the VCO output 216 of domain 11 with the VCO output 224 from domain 12. If inter domain phase/frequency skew between the two VCO outputs are detected, the secondary phase/frequency detector unit 220 may produce an output and provide an output to the main PLL 210 via the secondary feedback loop, in block 620. The output may be proportional to the inter domain phase/frequency skew, or may just indicate whether the phase/frequency of the output of the VCO 216 is leading or lagging with regard the output of the VCO 224. The main PLL 210 may then adjust the output of the VCO 216 accordingly, in block 630. The adjustment may be done by adjusting the output of the main charge pump 212, thereby subsequently adjusting the output of the VCO 216. The output of the VCO 216 may then be fed to the secondary PFD 221 and compared with the output of the VCO 216 again. The process may repeat indefinitely, until the inter domain phase/frequency skew is within a tolerance range.

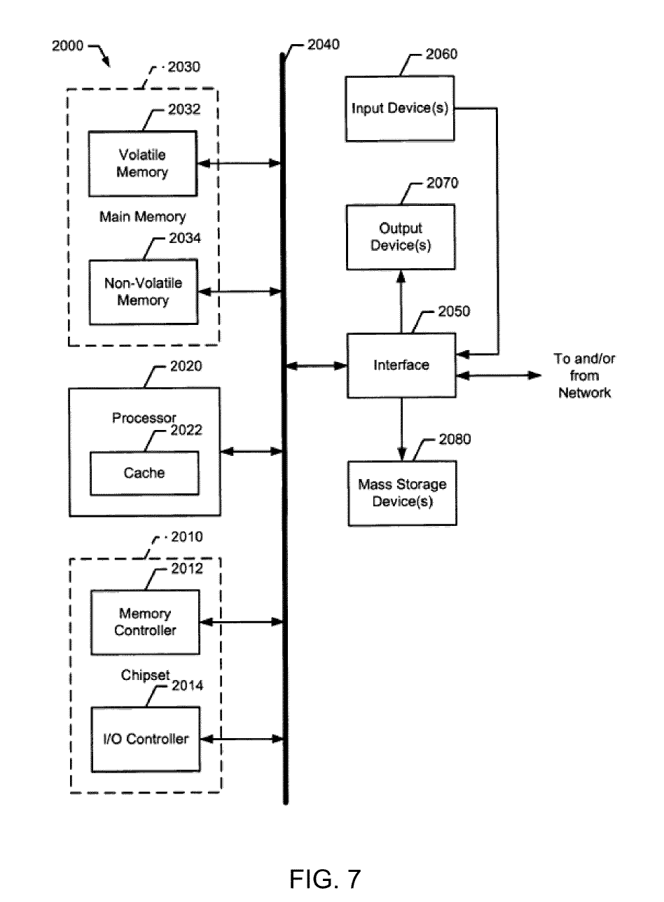

FIG. 7 illustrates a block diagram of an example apparatus comprising a processor system 2000 configured with the circuits disclosed herein. The processor system 2000 may be a desktop computer, a laptop computer, a handheld computer, a tablet computer, a Personal Digital Assistant (PDA), a mobile phone, a media player, a server, an Internet appliance, and/or any other type of processor based device.

The processor system 2000 illustrated in FIG. 7 may include a chipset 2010, which includes a memory controller 2012 and an input/output (I/O) controller 2014. The chipset 2010 may provide memory and I/O management functions as well as a plurality of general purpose and/or special purpose registers, timers, etc. that are accessible or used by a processor 2020. The processor 2020 may be implemented using one or more processors, WLAN components, WMAN components, WWAN components, and/or other suitable processing components. For example, the processor 2020 may be a multi-core processor endowed with the XF-PLL as previously described, including the XF-PLL illustrated in FIGS. 2-4. The processor 2020 may include a cache 2022, which may be implemented using a first-level unified cache (L1), a second-level unified cache (L2), a third-level unified cache (L3), and/or any other suitable structures to store data.

The memory controller 2012 may perform functions that enable the processor 2020 to access and communicate with a main memory 2030 including a volatile memory 2032 and a non-volatile memory 2034 via a bus 2040. The volatile memory 2032 may be implemented by Synchronous Dynamic Random Access Memory (SDRAM), Dynamic Random Access Memory (DRAM), RAMBUS Dynamic Random Access Memory (RDRAM), and/or any other type of random access memory device. The non-volatile memory 2034 may be implemented using flash memory, Read Only Memory (ROM), Electrically Erasable Programmable Read Only Memory (EEPROM), and/or any other desired type of memory device.

The processor system 2000 may also include an interface circuit 2050 that is coupled to the bus 2040. The interface circuit 2050 may be implemented using any type of interface standard such as an Ethernet interface, a universal serial bus (USB), a third generation input/output interface (3GIO) interface, PCI Express, Serial ATA, PATA, and/or any other suitable type of interface.

One or more input devices 2060 may be coupled to the interface circuit 2050. The input device(s) 2060 permit an individual to enter data and commands into the processor 2020. For example, the input device(s) 2060 may be implemented by a keyboard, a mouse, a touch-sensitive display, a track pad, a track ball, an isopoint, and/or a voice recognition system.

One or more output devices 2070 may also be coupled to the interface circuit 2050. For example, the output device(s) 2070 may be implemented by display devices (e.g., a light emitting display (LED), a liquid crystal display (LCD), a cathode ray tube (CRT) display, a printer and/or speakers). The interface circuit 2050 may include, among other things, a graphics driver card.

The processor system 2000 may also include one or more mass storage devices 2080 to store software and data. Examples of such mass storage device(s) 2080 include floppy disks and drives, hard disk drives, compact disks and drives, and digital versatile disks (DVD) and drives.

The interface circuit 2050 may also include a communication device such as a modem or a network interface card to facilitate exchange of data with external computers via a network. The communication link between the processor system 2000 and the network may be any type of network connection such as an Ethernet connection, a digital subscriber line (DSL), a telephone line, a cellular telephone system, a coaxial cable, etc.

Access to the input device(s) 2060, the output device(s) 2070, the mass storage device(s) 2080 and/or the network may be controlled by the I/O controller 2014. In particular, the I/O controller 2014 may perform functions that enable the processor 2020 to communicate with the input device(s) 2060, the output device(s) 2070, the mass storage device(s) 2080 and/or the network via the bus 2040 and the interface circuit 2050.

In various embodiments, other elements of FIG. 7 may also practice the circuits of the present disclosure earlier described. Further, while the components shown in FIG. 9 are depicted as separate blocks within the processor system 2000, the functions performed by some of these blocks may be integrated within a single semiconductor circuit or may be implemented using two or more separate integrated circuits. For example, although the memory controller 2012 and the I/O controller 2014 are depicted as separate blocks within the chipset 2010, the memory controller 2012 and the I/O controller 2014 may be integrated within a single semiconductor circuit.

Although certain example methods, apparatus, and articles of manufacture have been described herein, the scope of coverage of this disclosure is not limited thereto. On the contrary, this disclosure covers all methods, apparatus, and articles of manufacture fairly falling within the scope of the appended claims either literally or under the doctrine of equivalents. For example, although the above discloses example systems including, among other components, software or firmware executed on hardware, it should be noted that such systems are merely illustrative and should not be considered as limiting. In particular, it is contemplated that any or all of the disclosed hardware, software, and/or firmware components could be embodied exclusively in hardware, exclusively in software, exclusively in firmware or in some combination of hardware, software, and/or firmware.

What is claimed is:

1. An apparatus comprising:
a first domain having a first phase-locked loop (PLL);
a second domain having a second PLL, the second domain being adjacent to the first domain, wherein
the first PLL is configured to receive a first input from an output of the first PLL and a second input from an output of the second PLL, and
the second PLL is configured to receive a third input from the output of the first PLL and a fourth input from the output of the second PLL to form a cross feedback relationship between the first PLL and the second PLL.

2. The apparatus of claim 1, wherein the first PLL further comprises:
a main phase or frequency detector configured to receive the first input;
a main charge pump and a voltage controlled oscillator (VCO) coupled to the main phase or frequency detector to form a main feedback loop; and
a first secondary phase or frequency detection unit coupled to the main feedback loop, the first secondary phase or frequency detection unit configured to receive the second input and the output of the first PLL.

3. The apparatus of claim 2, wherein the output of the first PLL is coupled to the second PLL of the second domain via another secondary phase or frequency detector unit coupled to the second PLL.

4. The apparatus of claim 2, wherein the first secondary phase or frequency detector unit comprises a secondary phase/frequency detector and a secondary charge pump.

5. The apparatus of claim 2, wherein the first secondary phase or frequency detector unit comprises a lead/lag detector configured to cause the main charge pump to increase or decrease a current by a predefined amount.

6. The apparatus of claim 2, wherein the first secondary phase or frequency detector unit is configured to be disabled during initial locking period of the first PLL.

7. The apparatus of claim 2, wherein the first secondary phase or frequency detector unit comprises a phase detector.

8. The apparatus of claim 4, wherein the secondary charge pump is structurally similar to the main charge pump and configured to produce a fraction of a current compared to the main charge pump.

9. The apparatus of claim 2, wherein the first PLL further comprises:
a second secondary phase or frequency detection unit coupled to the main feedback loop, the second secondary phase or frequency detection unit configured to receive the output of the first PLL and an output from a third PLL of a third domain to form a cross feedback relationship with the third domain, the third domain being adjacent to the first domain.

10. The apparatus of claim 1, wherein the apparatus is a multi-core microprocessor comprising a plurality of domains with a one-dimensional or two-dimensional layout.

11. A method comprising:
receiving, by a secondary phase frequency detector unit disposed on an integrated circuit comprising multiple domains, a first input signal based on an output of a main phase-locked loop (PLL) of a first domain and a second input signal based on an output of a second PLL of a second domain, the second domain being adjacent to the first domain;
detecting, by the secondary phase or frequency detection unit, a phase or frequency difference between the first and the second input signal; and
adjusting the output of the main PLL at least partially based on detected phase or frequency difference.

12. The method of claim 11, wherein the adjusting the output of the main PLL further comprising adjusting an output of a main charge pump of the main PLL at least partially based on the detected phase or frequency difference.

13. The method of claim 11, wherein the secondary phase or frequency detector unit comprises a lead/lag detector, and the main PLL comprises a charge pump, and the method further comprising:
increasing or decreasing an output of the charge pump by a predefined amount at least partially based on whether a phase/frequency of the first input signal is leading or lagging with respect to the second input signal.

14. The method of claim 11, further comprising:
disabling the secondary phase/frequency detector unit during initial locking period of the main PLL.

15. The method of claim 11, wherein the secondary phase or frequency detector unit comprises a secondary charge pump, and the method further comprising:
adjusting an output of the secondary charge pump based on a secondary charge pump v. main charge pump current ratio.

16. A system comprising:
a memory controller disposed on a die;
a plurality of execution units disposed on a die coupled to the memory controller, wherein respective ones of the plurality of execution units are adjacent to one or more neighboring executing units and the respective ones of the plurality of execution units further comprise a cross-feedback phase-locked loop (XF-PLL) configured to receive a main input from an output of the XF-PLL and one or more secondary inputs respectively from one or more outputs of one or more XF-PLL's of the corresponding one or more neighboring execution units.

17. The system of claim 16, wherein the XF-PLL further comprises:
a main phase or frequency detector configured to receive the main input;
a main charge pump and a voltage controlled oscillator (VCO) coupled to the main phase or frequency detector to form a main feedback loop;
one or more secondary phase or frequency detector units coupled to the main feedback loop, the one or more secondary phase or frequency detector configured to respectively receive the one or more secondary inputs.

18. The system of claim 17, wherein the one or more secondary phase or frequency detectors are configured to receive an output of the VCO.

19. The system of claim 17, wherein respective ones of the one or more secondary phase or frequency detector units comprise a secondary phase/frequency detector and a secondary charge pump.

20. The system of claim 17, wherein respective ones of the one or more secondary phase or frequency detector units comprise a lead/lag detector configured to cause the main charge pump to increase or decrease a current by a predefined amount.

21. The system of claim 17, wherein respective ones of the one or more secondary phase or frequency detector units comprise a phase detector.

22. The system of claim 19, wherein respective ones of the secondary charge pump is structurally similar to the main charge pump and configured to produce a fraction of a current compared to the main charge pump.
